(19) United States
(12) Patent Application Publication
(10) Pub. No.: US 2011/0260148 A1
(43) Pub. Date: Oct. 27, 2011

(54) TRANSMISSIVE ORGANIC LIGHT EMITTING DIODE AND TRANSMISSIVE LIGHTING DEVICE USING THE SAME

(75) Inventors: Joo Won Lee, Seoul (KR); Hye Yong Chu, Daejeon (KR); Jong Hee Lee, Daejeon (KR); Jeong Ik Lee, Gyeonggi-do (KR)

(73) Assignee: ELECTRONICS AND TELECOMMUNICATIONS RESEARCH INSTITUTE, Daejeon (KR)

(21) Appl. No.: 13/092,767

(22) Filed: Apr. 22, 2011

(30) Foreign Application Priority Data
Apr. 23, 2010 (KR) 10-2010-0037777

(51) Int. Cl. H01L 51/52

(52) U.S. Cl. 257/40; 257/E51.018

(57) ABSTRACT

A transmissive organic light emitting diode (OLED) with improved external light efficiency and a transmissive lighting device including the same are provided. The OLED includes a transparent anode formed on a substrate, an organic emission layer formed on the transparent anode, a cathode formed on the organic emission layer, and a light extraction enhancing layer formed on the transparent cathode, and configured to change a path of light generated from the organic emission layer to enhance light extraction efficiency of the OLED. The external light extraction efficiency is enhanced in both-sided or single-sided emission of the OLED and the external light extraction efficiencies of bottom and top surfaces of the OLED are selectively or simultaneously enhanced. An external light extraction ratio between the bottom and top surfaces in both-sided emission is controlled.

### CROSS-REFERENCE TO RELATED APPLICATION

This application claims priority to and the benefit of Korean Patent Application No. 10-2010-0037777, filed Apr. 23, 2010, the disclosure of which is incorporated herein by reference in its entirety.

### BACKGROUND

1. Field of the Invention

The present invention relates to a transmissive organic light emitting diode (OLED) and a transmissive lighting device including the same, and more specifically, to a transmissive OLED with improved external light efficiency and a transmissive lighting device including the same.

2. Discussion of Related Art

Conventionally, incandescent lamps or fluorescent lamps have mostly been used as lighting devices. The incandescent lamps have low efficiency and a short life span and the fluorescent lamps include a heavy metal such as mercury, lead, etc.

Accordingly, studies on organic light emitting diodes (OLEDs) as next generation lighting devices have been actively conducted. The OLEDs are environmentally friendly due to non-use of heavy metals and are highly likely to be used as high efficiency light sources. In addition, the OLEDs may be fabricated in many types, such as a point light source, a line light source, and a surface light source as compared with the conventional lighting devices.

Hereinafter, the structure and operation principle of the conventional OLED and the problems will be described with reference to the drawings.

FIG. 1 is a cross-sectional view illustrating a structure of the conventional OLED.

Referring to FIG. 1, the conventional OLED includes an anode 120, an organic emission layer 130 and a cathode 140 which are sequentially stacked on a substrate 110.

Herein, the anode 120 and the cathode 140 are formed of transparent electrodes, semi-transparent electrodes, or opaque electrodes depending on a desired emitting type. In general, indium tin oxide (ITO), which has high light transmissivity, is formed as the transparent electrode for the anode 120 or the cathode 140.

The organic emission layer 130 includes a hole injection layer (HIL) 130A which facilitates the injection of holes from the anode 120, a hole transporting layer (HTL) 130B which facilitates the transport of the holes injected via the HIL 130A, an emission layer (EML) 130C, an electron transporting layer (ETL) 130D which facilitates the transport of electrons to the EML 130C, and an electron injection layer (EIL) 130E which facilitates the injection of electrons from the cathode 140.

The operation principle of the conventional OLED having the above structure will be described as follows.

First, if driving voltages are applied to the anode 120 and the cathode 140, the holes in the HIL 130A are supplied to the EML 130C via the HTL 130B and the electrons in the EIL 130E are supplied to the EML 130C via the ETL 130D. The holes and electrons supplied in the EML 130C are combined with each other to emit light in the EML 103C.

On the other hand, double-sided emission OLEDs for top and bottom emission should include a transparent cathode. Accordingly, a method of forming a transparent cathode as a material for increasing light transmissivity or a method of improving the structure of the OLED to lower electrical conductivity of the transparent cathode has been studied.

However, as described above, although the conventional OLED includes the transparent cathode, as a microcavity effect due to a metal used as the cathode is entirely formed in the device, there is still a limit in effectively extracting total photons generated within the device externally.

### SUMMARY OF THE INVENTION

The present invention is directed to an organic light emitting diode (OLED) including a light extraction enhancing layer capable of changing a path of light generated from an organic emission layer to enhance light extraction efficiency of the OLED and a transmissive lighting device using the same.

One aspect of the present invention provides a transmissive OLED including a transparent anode formed on a substrate, an organic emission layer formed on the transparent anode, a transparent cathode formed on the organic emission layer, and a light extraction enhancing layer formed on the transparent cathode, changing a path of light generated from the organic emission layer to enhance light extraction efficiency of the OLED.

Another aspect of the present invention provides a transmissive lighting device having a structure using a transmissive OLED as a light source. The transmissive OLED includes a transparent anode formed on a substrate, an organic emission layer formed on the transparent anode, a transparent cathode formed on the organic emission layer, and a light extraction enhancing layer formed on the transparent cathode, changing a path of light generated from the organic emission layer to enhance light extraction efficiency of the OLED.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a cross-sectional view illustrating the structure of a conventional organic light emitting diode (OLED);

FIG. 2 is a cross-sectional view illustrating the structure of a transmissive OLED according to embodiments of the present invention;

FIG. 3A is a cross-sectional view illustrating the structure of a transmissive OLED according to an exemplary embodiment of the present invention;

FIGS. 3B and 3C are graphs showing characteristics of the OLED of FIG. 3A;

FIG. 4A is a cross-sectional view illustrating the structure of an OLED according to another exemplary embodiment of the present invention; and

FIGS. 4B and 4C are graphs showing characteristics of the OLED of FIG. 4A.

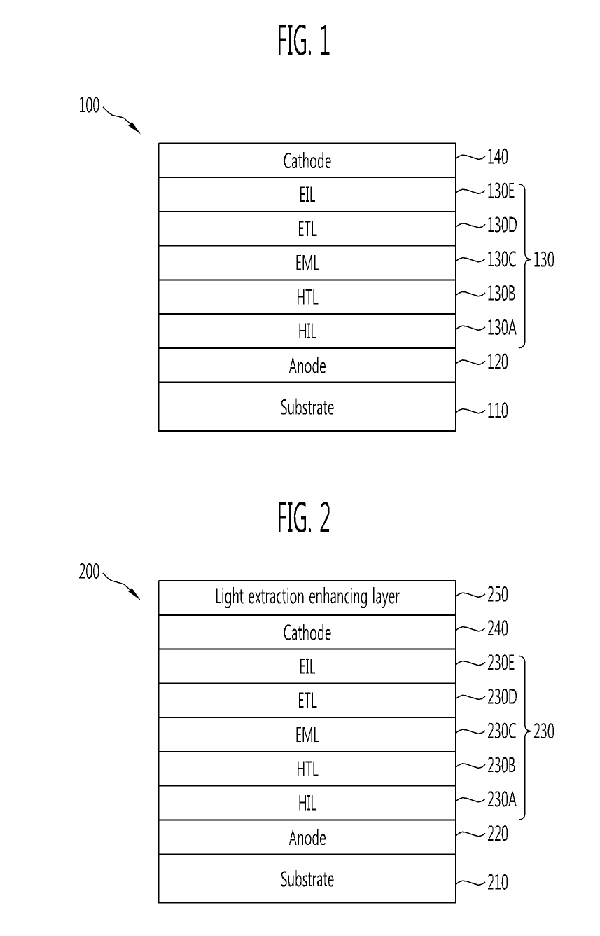

### DETAILED DESCRIPTION OF EMBODIMENTS

The present invention will be described more fully hereinafter with reference to the accompanying drawings, in which exemplary embodiments of the invention are shown. This invention may, however, be embodied in different forms and should not be construed as limited to the embodiments set forth herein. In drawings, portions unrelated to description will be omitted to distinctly describe the present invention and similar reference numerals are labeled to similar portions throughout the specification.

FIG. 2 is a cross-sectional view illustrating the structure of a transmissive organic light emitting diode (OLED) according to embodiments of the present invention.

organic emission layer 230, and a light extraction enhancing Referring to FIG. 2, an OLED 200 includes a transparent anode 220 formed on a substrate 210, an organic emission layer 230 formed on the transparent anode 220, a transparent cathode 240 formed on the layer 250 formed on the transparent cathode and configured to change a path of light generated from the organic emission layer 230 to enhance light extraction efficiency.

In addition, the organic emission layer 230 includes a hole injection layer (HIL) 230A, a hole transporting layer (HTL) 230B, an emission layer (EML) 230C, an electron transporting layer (ETL) 230D, and an electron injection layer (EIL) 230E.

The transparent anode 220 or the transparent cathode 240 may be formed of a combination of lithium fluoride (LiF), aluminum (Al), and silver (Ag) and may further include magnesium (Mg), cesium (Cs), etc.

The organic emission layer 230 is formed of an organic material. For example, the EML 230C may include a red EML, a green EML, a blue EML and a white EML including the red, green and blue EMLs or include a monochromatic EML including any one of the red, green and blue EMLs.

The EIL 230E and the ETL 230D may be formed by doping an N-type metal into an organic layer. Alternatively, the EIL 230E may be formed by doping an N type metal into an organic layer for the ETL 230D.

Herein, one or more metal materials selected from the group consisting of an alkali metal such as lithium (Li), sodium (Na), potassium (K), rubidium (Rb), Cs, francium (Fr), ununennium (Uue), etc. and an alkaline earth metal such as beryllium (Be), Mg, calcium (Ca), strontium (Sr), barium (Ba), radium (Ra), etc. may be used as the doping metal.

In addition, a ratio of the metal doped into the organic layer may be properly adjusted in a range of 0 to 90%.

The light extraction enhancing layer 250 serves to change the path of the light generated from the organic emission layer 230 to enhance an external light extraction efficiency. Herein, the light extraction efficiency denotes a ratio of an amount of externally extracted light to an amount of the light emitted from the organic emission layer 230 of the OLED.

In drawings, although the light extraction enhancing layer 250 is illustrated as a single layer, it may be formed of multiple layers. For example, the light extraction enhancing layer 250 may be formed of 10 or less layers.

The light extraction enhancing layer 250 may be formed of an organic material or an inorganic material having a refractive index (n) of 1 to 2.5 in a visible ray region, or formed of a combination of the organic and inorganic materials. In addition, if the light extraction enhancing layer 250 is formed of the multiple layers, the respective layers may be formed of materials having different refractive indices. For example, the light extraction enhancing layer 250 may include low and high refractive materials, low, medium, and high refractive materials, or medium, low, and high refractive materials which are sequentially stacked. In addition, the light extraction enhancing layer 250 may include the multiple layers stacked in various orders based on an optical theory.

The light extraction enhancing layer 250 may have a thickness of 10 nm to 1000 nm depending on a spectrum of an emitting material of a light source. If the light extraction enhancing layer 250 includes the multiple layers, each layer may have a thickness of 10 nm to 1000 nm. Especially, the thickness of the light extraction enhancing layer 250 may be determined depending on the waveform of the light.

The light extraction enhancing layer 250 may be formed by thermal evaporation, E-beam evaporation, sputtering, spin coating, chemical vapor deposition, etc. The light extraction enhancing layer 250 may be formed by mixing these methods or by using these methods sequentially.

A transmissive white OLED including the light extraction enhancing layer 250 may externally emit 30 to 80% of the light generated from the organic emission layer 230, and transmissive red, green and blue OLEDs may also emit 30 to 80% of the light generated from the organic emission layer 230 externally.

That is, the light extraction enhancing layer 250 changes the path of the light generated from the organic emission layer 230 to enhance the external light extraction efficiency of the OLED. Accordingly, the OLED suitable for a light source of a lighting device can be provided.

Exemplary embodiments of an OLED including a light extraction enhancing layer will be described hereinafter.

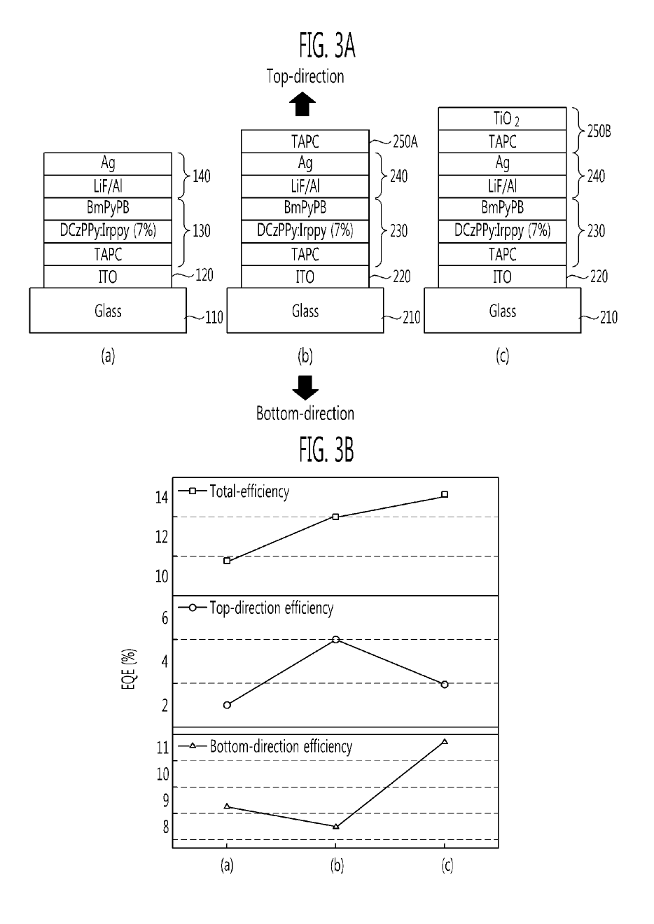

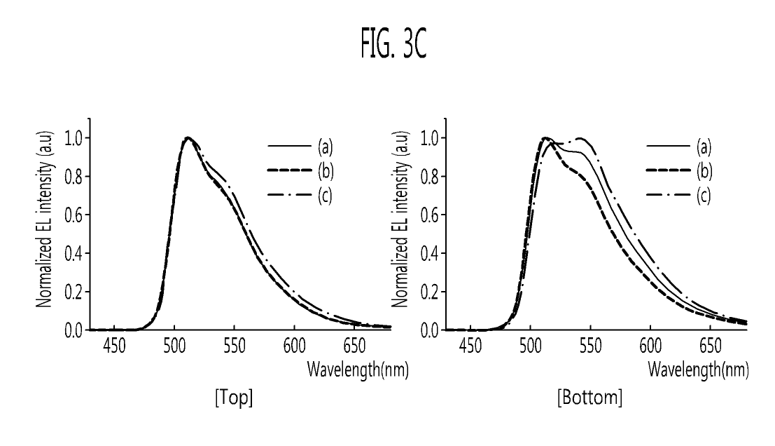

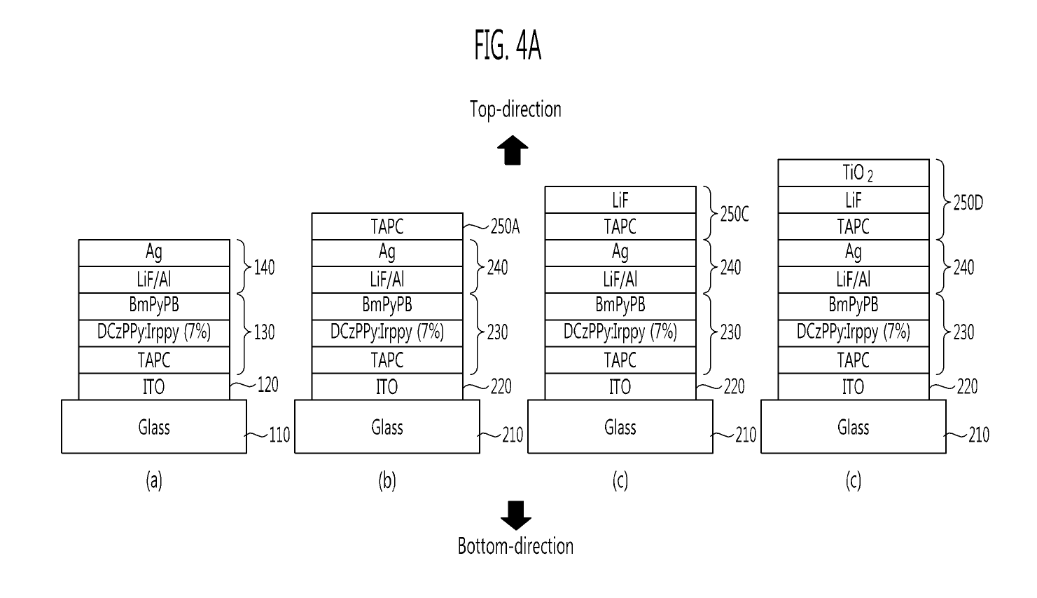

FIG. 3A is a cross-sectional view illustrating the structure of a transmissive OLED in an exemplary embodiment of the present invention and FIGS. 3B and 3C are graphs showing characteristics of the OLED of FIG. 3A. The exemplary embodiment selectively enhancing light extraction efficiency of the bottom surface of the OLED will be described.

FIG. 3A shows a cross-section of an OLED of an exemplary embodiment of the present invention. Referring to FIG. 3A, an OLED 200 of the exemplary embodiment includes an anode 220, an organic emission layer 230, a cathode 240, and a light extraction enhancing layer 250A or 250B which are sequentially stacked on a substrate 210.

In FIG. 3A, (a) illustrates the cross-section of the conventional OLED, (b) illustrates the cross-section of the OLED in which the light extraction enhancing layer 250A is formed of a single layer of TAPC having a refractive index (n) of 1.78, and (c) illustrates the cross-section of the OLED in which the light extraction enhancing layer 250B is formed of multiple layers of TAPC having a refractive index (n) of 1.78 and titanium oxide (TiO₂) having a refractive index (n) of 2.4.

The following table I shows a specific material and a thickness of each of the layers.

TABLE I

| | Material | Thickness (nm) |
|---|---|---|
| Light extraction | TiO2 | 55 |
| enhancing layer | TAPC | 75 |
| Cathode | Ag | 15 |
| | Al | 1.5 |
| | LiF | 1.0 |
| ETL | BmPyPB | 60 |
| EML | DCzPPy: Irppy(7%) | 20 |
| HTL | TAPC | 60 |

Herein, DCzPPy:Irppy(7%) denotes DCzPPy doped with Irppy by 7%.
BmPyPB denotes 1,3-bis(3,5-dipyrid-3-yl-phenyl)bezen.
TAPC denotes 1,1-bis[4-[N,N-di(4-tolyl)amino]phenyl]cyclohexane.

FIG. 3B is a graph showing the external light extraction characteristics of the OLED, and FIG. 3C is a graph showing a normalized electroluminescence (EL) intensity of the OLED. In addition, the following table II shows external quantum efficiency (EQE) of the OLED of the exemplary embodiment of the present invention.

TABLE II

| | Bottom | Top | EQE |
|---|---|---|---|
| (a) | 8 | 2 | 10% |
| (b) | 7 | 5 | 12% |
| (c) | 11.2 | 3 | 14.2% |

It can be understood from FIGS. 3B and 3C and table II that the external light extraction efficiency is increased by forming the light extraction enhancing layer 250A or 250B. In particular, it can be understood that the light extraction enhancing layer 250A or 250B having a larger refractive index than air selectively enhances the light extraction efficiency of the bottom surface of the OLED by total reflection property according to a refractive index difference between the light extraction enhancing layer 250A or 250B and the air.

In addition, it can be understood that as the light extraction enhancing layer 250B is formed of the multiple layers which have higher refractive indices upwardly, the light extraction efficiency of the bottom surface of the OLED can be effectively enhanced.

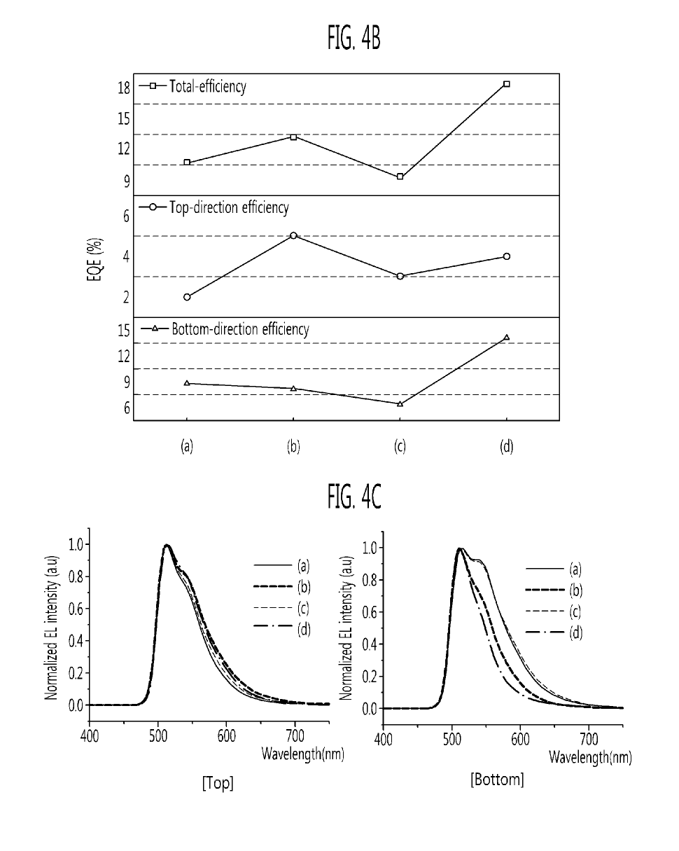

FIG. 4A is a cross-sectional view illustrating the structure of an OLED in another exemplary embodiment of the present invention, and FIGS. 4B and 4C are graphs showing characteristics of the OLED of FIG. 4A. The other exemplary embodiment controlling a light extraction ratio between the bottom and top surfaces of the OLED by externally emitting a portion of light arrived at an uppermost cross-section of a light extraction enhancing layer and by totally reflecting another portion of the light will be described.

FIG. 4A illustrates a cross-section of the OLED of another exemplary embodiment of the present invention. Referring to FIG. 4A, an OLED 200 of the other exemplary embodiment includes an anode 220, an organic light emission layer 230, a cathode 240, and a light extraction enhancing layer 250A, 250C or 250D which are sequentially stacked on a substrate 210.

In FIG. 4A, (a) indicates a cross-section of the conventional OLED, (b) indicates a cross-section of the OLED in which the light extraction enhancing layer 250A is formed of a single layer of TAPC having a refractive index (n) of 1.78, (c) indicates a cross-section of the OLED in which the light extraction enhancing layer 250C is formed of multiple layers of TAPC having a refractive index (n) of 1.78 and lithium fluoride (LiF) having a refractive index (n) of 1.39, and (d) indicates a cross-section of the OLED in which the light extraction enhancing layer 250D is formed of multiple layers of TAPC having a refractive index (n) of 1.78, lithium fluoride (LiF) having a refractive index (n) of 1.39, and titanium oxide (Ti_{O2}) having a refractive index (n) of 2.4.

The following table III shows a specific material and a thickness of each layer.

TABLE III

| | Material | Thickness (nm) |
|---|---|---|
| Light extraction | TiO2 | 55 |
| enhancing layer | LiF | 91 |
| | TAPC | 75 |
| Cathode | Ag | 15 |
| | Al | 1.5 |
| | LiF | 1.0 |
| ETL | BmPyPB | 60 |
| EML | DCzPPy: Irppy(7%) | 20 |
| HTL | TAPC | 60 |

FIG. 4B is a graph showing an external light extraction characteristic of the OLED, and FIG. 4C is a graph showing a normalized EL intensity of the OLED. In addition, the following table IV indicates EQE of the OLED of the other exemplary embodiment of the present invention.

TABLE IV

| | Bottom | Top | EQE |
|---|---|---|---|
| (a) | 8 | 2 | 10% |
| (b) | 7 | 5 | 12% |
| (c) | 6.5 | 3 | 9.5% |
| (d) | 14 | 4 | 18% |

It can be understood from FIGS. 4B and 4C and table IV that the external light extraction efficiency is increased by forming the light extraction enhancing layer 250A, 250C or 250D. In particular, it can be understood that an external light extraction ratio between the bottom and top surfaces of the OLED can be controlled according to refractive indices, a stack order based on the refractive indices or thicknesses of the multiple layers by forming the light extraction enhancing layer 250A, 250C or 250D of the multiple layers.

Although the exemplary embodiment explains a structure of an OLED including a light extraction enhancing layer, the exemplary embodiment may also be applied equally to a transmissive lighting device having a structure using the OLED including the light extraction enhancing layer as a light source.

According to the present invention, a structure of an OLED having a weak microcavity is improved by forming a light extraction enhancing layer on a cathode to increase an external light extraction efficiency of the OLED. In particular, by controlling a refractive index, a stack order based on the refractive index, and a thickness of the light extraction enhancing layer, the external light extraction efficiency in both-sided or single-sided emission of the OLED can be improved and the external light extraction efficiencies of the bottom and top surfaces of the OLED can be selectively or simultaneously improved. In addition, a light extraction ratio between the bottom and top surfaces in both-sided emission of the OLED can be controlled.

In an exemplary embodiment, the light extraction efficiency of the bottom surface of the OLED can be improved by changing a light path by the light extraction enhancing layer using total reflection property according to a refractive index difference between the high refractive light extraction enhancing layer on the top surface of the OLED and air.

In another exemplary embodiment, the light extraction ratio between the top and bottom surfaces of the OLED can be controlled according to refractive indices, a stacking order based on the refractive indices, and thicknesses of multiple layers by forming the light extraction enhancing layer of the multiple layers.

In the drawings and specification, there have been disclosed typical exemplary embodiments of the invention and, although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A transmissive organic light emitting diode (OLED), comprising:
a transparent anode formed on a substrate;
an organic emission layer formed on the transparent anode;
a transparent cathode formed on the organic emission layer; and
a light extraction enhancing layer formed on the transparent cathode, and configured to change a path of light generated from the organic emission layer to improve light extraction efficiency of the OLED.

2. A transmissive lighting device, comprising a transmissive organic light emitting diode (OLED) as a light source,
wherein the transmissive OLED includes:
a transparent anode formed on a substrate;
an organic emission layer formed on the transparent anode;
a transparent cathode formed on the organic emission layer; and
a light extraction enhancing layer formed on the transparent cathode, and configured to change a path of light generated from the organic emission layer to enhance light extraction efficiency of the OLED.

3. The transmissive lighting device of claim 2, wherein the light extraction enhancing layer enhances the light extraction efficiency of a bottom surface of the OLED using a total reflection property according to a refractive index difference between the light extraction enhancing layer and air.

4. The transmissive lighting device of claim 3, wherein the light extraction enhancing layer is formed of a single layer or multiple layers having different refractive indices, the multiple layers having higher refractive indices upwardly from the substrate.

5. The transmissive lighting device of claim 2, wherein the light extraction enhancing layer is formed of multiple layers, and a light extraction ratio between bottom and top surfaces of the OLED is controlled by refractive indices of the multiple layers, a stacking order of the multiple layers based on the refractive indices, and thickness of each of the multiple layers.

6. The transmissive lighting device of claim 2, wherein the light extraction enhancing layer is formed of any one of an organic material, an inorganic material and a combination thereof.

7. The transmissive lighting device of claim 2, wherein the light extraction enhancing layer is formed of a material having a refractive index (n) of 1 to 2.5.

8. The transmissive lighting device of claim 2, wherein the light extraction enhancing layer has a thickness of 10 nm to 1000 nm.
